(19) United States
(12) Patent Application Publication
(10) Pub. No.: US 2023/0282496 A1
(43) Pub. Date: Sep. 7, 2023

(54) SUBSTRATE HEATING APPARATUS AND SUBSTRATE PROCESSING APPARATUS

(71) Applicant: Tokyo Electron Limited, Tokyo (JP)

(72) Inventor: Manabu HONMA, Iwate (JP)

(21) Appl. No.: 18/115,366

(22) Filed: Feb. 28, 2023

(30) Foreign Application Priority Data
Mar. 7, 2022 (JP) 2022-034478

(51) Int. Cl. H01L 21/67; H01L 21/673

(52) U.S. Cl. CPC H01L 21/67103; H01L 21/67336

(57) ABSTRACT

A substrate heating apparatus includes: an induction heating coil; a holding tray including a substrate holder that places and holds a substrate thereon, and configured to be induction-heated by the induction heating coil; and a rotary table configured to support the holding tray and provided to be freely rotatable.

### CROSS-REFERENCE TO RELATED APPLICATIONS

This application is based on and claims priority from Japanese Patent Application No. 2022-034478, filed on Mar. 7, 2022, with the Japan Patent Office, the disclosure of which is incorporated herein in its entirety by reference.

### TECHNICAL FIELD

The present disclosure relates to a substrate heating apparatus and a substrate processing apparatus.

### BACKGROUND

Japanese Patent Laid-Open Publication No. 2014-127612 discloses an apparatus of manufacturing an epitaxial wafer, which includes: a mounting plate having a plurality of concave accommodations each accommodating a wafer support table for placing a wafer thereon and arranged side by side circumferentially; a ceiling disposed to face the upper surface of the mounting plate; and an induction coil that is disposed to face the lower surface of the mounting plate and the upper surface of the ceiling, and heats the mounting plate and the ceiling by an induction heating.

### SUMMARY

According to an aspect, a substrate heating apparatus includes: an induction heating coil; a holding tray including a substrate holder that places and holds a substrate thereon, and configured to be induction-heated by the induction heating coil; and a rotary table configured to support the holding tray and provided to be freely rotatable.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating an example of a substrate processing apparatus according to an embodiment.

FIG. 2 is a view illustrating an internal structure of a chamber according to an embodiment.

FIG. 3 is a view illustrating an example of a hardware configuration of a control unit according to an embodiment.

FIG. 4 is an example of a cross-sectional view illustrating a structure of an accommodation and a support tray of a rotary table.

FIG. 5 is another example of the cross-sectional view illustrating the structure of the accommodation recess and the support tray of the rotary table.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure will be described with reference to the drawings. In the respective drawings, the same components will be denoted by the same reference numerals, and overlapping descriptions thereof may be omitted.

[Substrate Processing Apparatus]

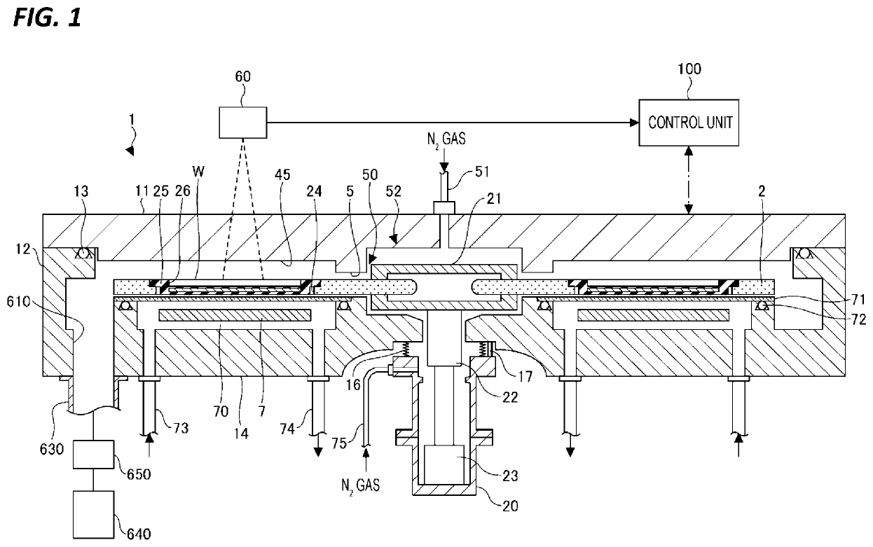

First, a substrate processing apparatus according to an embodiment will be described with reference to FIGS. 1 to 3. FIG. 1 is a schematic cross-sectional view illustrating an example of the substrate processing apparatus according to the embodiment. In the descriptions herein below, it is assumed that the substrate processing apparatus is a film forming apparatus.

The substrate processing apparatus of the present disclosure includes a chamber 1 having a substantially circular planar shape, and a rotary table 2 provided in the chamber 1 and having a rotation center at the center of the chamber 1. The chamber 1 includes a container body 12 having a bottomed cylindrical shape, and a top plate 11 disposed airtightly and detachably on the upper surface of the container body 12 via a seal member 13 such as an O-ring.

The rotary table 2 is fixed to a cylindrical core 21 at its center, and the core 21 is rotatably fixed to the upper end of a rotary shaft 22 that extends vertically. The rotary shaft 22 passes through a bottom 14 of the chamber 1, and its lower end is attached to a driving unit 23 that rotates the rotary shaft 22 around a vertical axis. The rotary shaft 22 and the driving unit 23 are accommodated in a cylindrical housing body 20 opened at its upper surface. A bellows 16 is provided between the bottom 14 of the container body 12 and the housing body 20. As a result, the housing body 20 is airtightly attached to the lower surface of the bottom 14 of the chamber 1, and the internal atmosphere of the housing body 20 is isolated from the atmosphere outside. The driving unit 23 may be a motor.

A lifting mechanism 17 is provided outside the bellows 16 to move the rotary table 2 up and down, thereby changing the height of the rotary table 2. The rotary table 2 is moved up and down by the lifting mechanism 17, so that the distance between a ceiling surface 45 and a wafer W may be changed in accordance with the upward/downward movement of the rotary table 2. The lifting mechanism 17 may be implemented with various configurations as long as the rotary table 2 may be moved up and down, and may have, for example, a structure in which the length of the rotary shaft 22 is increased or reduced by, for example, a gear.

A first exhaust port 610 is provided at the internal peripheral edge of the chamber 1 to communicate with an exhaust pipe 630. The exhaust pipe 630 is connected to a vacuum pump 640 via a pressure regulator 650, such that the inside of the chamber 1 may be exhausted from the first exhaust port 610.

The rotary table 2 is made of an insulating material such as quartz (SiO₂) or Al₂O₃. It is preferable that the rotary table 2 is made of an insulating material with a low heat conductivity such as quartz (SiO₂). The rotary table 2 is provided to be rotatable freely by the core 21, the rotary shaft 22, and the driving unit 23. The rotary table 2 is provided with an accommodating portion 24 that accommodates and supports a plurality of holding trays 25. In the example illustrated in FIG. 1 (and FIGS. 4 and 5 to be described later), the accommodating portion 24 is formed as a through hole penetrating the rotary table 2. However, the present disclosure is not limited thereto. The accommodating portion 24 may be formed as a bottomed recess that is formed in the upper surface of the rotary table 2 and is capable of accommodating the holding trays 25.

A circular recess (substrate holder) 26 is formed in the upper surface of each holding tray 25 to place and hold a semiconductor wafer (hereinafter, referred to as a “substrate” or a “wafer”) W therein. When the holding tray 25 is accommodated in the accommodating portion 24, the upper surface of the holding tray 25 (the upper surface outside the recess 26) and the upper surface of the rotary table 2 (the upper surface outside the accommodating portion 24) are flush with each other.

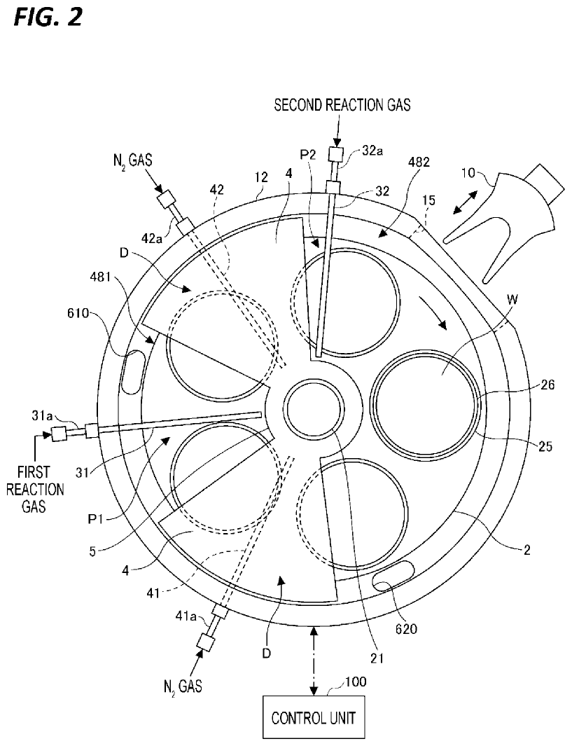

FIG. 2 is a view illustrating an internal structure of the chamber 1 according to the embodiment. FIG. 2 illustrates the internal structure of the chamber 1 while omitting the illustration of the top plate 11, when the substrate processing apparatus according to the embodiment is viewed from above.

As illustrated in FIG. 2, the plurality of (five in the illustrated example) holding trays 25 are provided along the rotation direction (circumferential direction) of the rotary table 2. The circular recess 26 is provided in each holding tray 25 to place a semiconductor wafer (hereinafter, referred to as a “substrate” or a “wafer”) W therein. FIG. 2 illustrates a state where the wafer W is placed in one recess 26. The recess 26 has an inner diameter slightly (e.g., 2 mm) larger than the diameter of the wafer W (e.g., 300 mm) and a depth substantially equal to the thickness of the wafer W, and is a placing unit capable of placing the wafer W therein. Thus, when the wafer W is placed in the recess 26 of the holding tray 25, the upper surface of the wafer W, the upper surface of the holding tray 25, and the upper surface of the rotary table 2 are flush with each other. In the bottom surface of the recess 26, through holes (not illustrated) are formed such that, for example, three lifting pins pass through the through holes to move the wafer W up and down while supporting the back surface of the wafer W. A transfer port 15 is provided to transfer the wafer W between an external transfer arm 10 and the rotary table 2.

The accommodating portion 24 of the rotary table 2 and the holding tray 25 will be described later with reference to FIGS. 4 and 5.

Reaction gas nozzles 31 and 32 and separation gas nozzles 41 and 42 each made of, for example, quartz are arranged above the rotary table 2. In the illustrated example, the separation gas nozzle 41, the reaction gas nozzle 31, the separation gas nozzle 42, and the reaction gas nozzle 32 are arranged in this order clockwise from the transfer port 15 (in the rotation direction of the rotary table 2) at intervals in the circumferential direction of the chamber 1. The nozzles 41, 31, 42, and 32 have gas introduction ports 41a, 31a, 42a, and 32a as their respective base ends, and the gas introduction ports 41a, 31a, 42a, and 32a are fixed to the outer peripheral wall of the container body 12. Accordingly, the nozzles are introduced into the chamber 1 from the outer peripheral wall of the chamber 1, and extend parallel to the rotary table 2 along the radial direction of the container body 12.

A first reaction gas supply source is connected to the reaction gas nozzle 31 via an ON/OFF valve or a flow rate regulator (both not illustrated), and stores a first reaction gas. A second reaction gas supply source is connected to the reaction gas nozzle 32 via an ON/OFF valve or a flow rate regulator (both not illustrated), and stores a second reaction gas which reacts with the first reaction gas.

Here, the first reaction gas may be a gas containing a semiconductor element or a metal element, and may be selected from gases usable as an oxide film or a nitride film when turning into an oxide or a nitride. The second reactive gas is selected from an oxidizing gas or a nitriding gas, which may react with a semiconductor element or a metal element, thereby producing a semiconductor oxide or a semiconductor nitride, or a metal oxide or a metal nitride. Specifically, the first reaction gas may be an organic semiconductor gas or an organometallic gas, which contains a semiconductor element or a metal element. Further, the first reaction gas may be a gas having an adsorptive property to the surface of the wafer W. The second reactive gas may be an oxidizing gas or a nitriding gas, which may undergo an oxidation reaction or a nitridation reaction with the first reaction gas adsorbed to the surface of the wafer W, thereby depositing a reaction compound on the surface of the wafer W.

Specifically, for example, the first reaction gas is organic aminosilane such as diisopropylaminosilane or bis(tert-butylamino)silane (BTBAS), which is a silicon-containing reaction gas and forms SiO₂ as an oxide film or SiN as a nitride film. Further, the first reactive gas is tetrakis(dimethylamino)hafnium (hereinafter, referred to as “TDMAH”), which is a hafnium-containing reaction gas and forms HfO as an oxide film. Further, the first reaction gas is, for example, TiCl₄, which is a titanium-containing reaction gas and forms TiN as a nitride film. The second reaction gas is an oxidizing gas such as ozone gas (O₃) or oxygen gas (O₂). Further, the second reaction gas is a nitriding gas such as ammonia gas (NH₃).

Supply sources of a noble gas such as Ar or He or an inert gas such as nitrogen (N₂) gas are connected to the separation gas nozzles 41 and 42 via ON/OFF valves or flow rate regulators (all not illustrated). The inert gas supplied from the separation gas nozzles 41 and 42 is also referred to as a separation gas. In the embodiment, for example, N₂ gas is used as the inert gas.

In addition to the first reaction gas supply source, the second reaction gas supply source or the supply source of a noble gas such as Ar or He or an inert gas such as nitrogen (N₂) gas, which is also used as a separation gas, is connected to the reaction gas nozzle 31. A switch (not illustrated) is provided such that a gas to be supplied is switched by an operation of the switch. In addition to the second reaction gas supply source, the first reaction gas supply source or the supply source of an inert gas, which is also used as a separation gas, is connected to the reaction gas nozzle 32, and a switch (not illustrated) is provided such that a gas to be supplied is switched by an operation of the switch.

The region defined below the reaction gas nozzle 31 is a first processing region P1 where the first reaction gas is adsorbed to the wafer W. The region defined below the reaction gas nozzle 32 is a second processing region P2 where the first reaction gas adsorbed to the wafer W in the first processing region P1 is oxidized or nitrided.

In the chamber 1, two convex portions 4 are attached to the back surface of the top plate 11 to protrude toward the rotary table 2. The convex portions 4 make up separation regions D together with the separation gas nozzles 41 and 42. That is, the regions below the separation gas nozzles 41 and 42 serve as the separation regions D, which separate the first processing region P1 and the second processing region P2 and prevents the mixing of the first reaction gas and the second reaction gas. Each convex portion 4 has a substantially planar fan shape cut in an arc shape at the top portion thereof. In the present disclosure, the convex portion 4 is disposed such that the inner arc is connected to a protrusion 5 (see, e.g., FIG. 1) protruding from the ceiling surface 45, and the outer arc extends along the inner peripheral surface of the container body 12 of the chamber 1. As illustrated in FIG. 1, the protrusion 5 is provided to surround the outer periphery of the core 21 to which the rotary table 2 is fixed.

The convex portions 4 illustrated in FIG. 2 are attached to the back surface of the top plate 11. Thus, the lower surface of each convex portion 4 is lower than the ceiling surface 45 on both sides of the lower surface in the circumferential direction.

A groove (not illustrated) is formed at the center of each convex portion 4 in the circumferential direction, to accommodate each of the separation gas nozzles 41 and 42. Gas ejection holes are formed in the separation gas nozzles 41 and 42.

The reaction gas nozzles 31 and 32 are provided apart from the ceiling surface 45 and close to the wafer W. The N₂ gas supplied from the separation gas nozzle 42 acts as a counterflow to the first reaction gas from the first processing region P1 and the second reaction gas (oxidizing gas or nitriding gas) from the second processing region P2. Accordingly, the first reaction gas from the first processing region P1 and the second reaction gas from the second processing region P2 are separated by the convex portions 4 and the N₂ gas. Thus, the first reaction gas and the second reaction gas are suppressed from being mixed and reacting with each other in the chamber 1.

A first exhaust port 610 and a second exhaust port 620 are formed between the rotary table 2 and the inner peripheral surface of the container body 12. A pressure regulator (auto pressure controller (APC)) 650 is provided in an exhaust pipe 630 between the first exhaust port 610 and a vacuum pump 640 illustrated in FIG. 1. The second exhaust port 620 is also connected to a vacuum pump (not illustrated) via an exhaust pipe (not illustrated) provided with a pressure regulator. The exhaust pressures of the first exhaust port 610 and the second exhaust port 620 are independently controllable.

As illustrated in FIG. 1, an induction heating coil 7 is provided in a space 70 formed between the rotary table 2 and the bottom 14 of the chamber 1, to perform an inducting heating of the holding trays 25. A control unit 100 controls a radio-frequency power supply (not illustrated) that supplies a radio-frequency current to the induction heating coil 7. When the radio-frequency current is supplied from the radio-frequency power supply (not illustrated) to the induction heating coil 7, the holding tray 25 (magnetic members 250 and 252 to be described later) is heated by an induction heating. As a result, the wafer W placed in the recess 26 of the holding tray 25 is heated to a temperature (e.g., 450° C.) determined by a process recipe.

A partition plate 71 is provided between the induction heating coil 7 and the rotary table 2, to cover the space 70 where the induction heating coil 7 is disposed. The partition plate 71 is disposed airtightly with respect to the bottom 14 of the chamber 1 via a seal member 72 such as an O-ring. The partition plate 71 is made of an insulating material such as quartz (SiO₂) or Al₂O₃. Thus, a gas is suppressed from entering the space 70 where the induction heating coil 7 is provided.

In the bottom 14 of the chamber 1, a gas supply pipe 73 is provided to supply a cooling gas (e.g., N₂ gas) for air-cooling the induction heating coil 7 into the space 70, and a gas exhaust pipe 74 is provided to exhaust the cooling gas from the space 70. As a result, the heat of the induction heating coil 7 is exhausted to the outside of the space 70.

A plurality of induction heating coils 7 may be provided along the rotation direction (circumferential direction) of the rotary table 2, and may be each independently controllable. The number of induction heating coils 7 may be the same as the number of holding trays 25 accommodated and supported in the rotary table 2. As a result, the induction heating may be performed for a holding tray 25 selected from the plurality of holding trays 25, in a state where the rotary table 2 is stopped.

The induction heating coil 7, the holding trays 25, and the rotary table 2 make up a substrate heating apparatus that heats the wafer W held on the holding tray 25.

The distance between the induction heating coil 7 and the holding tray 25 may be within 20 mm.

The housing body 20 is provided with a purge gas supply pipe 75 that supplies N₂ gas as a purge gas to perform a purging. When the N₂ gas is supplied from the purge gas supply pipe 75, the flow of the N₂ gas may suppress the mixing of gases of spaces 481 and 482 illustrated in FIG. 2 through the space below the center of the chamber 1 and the space below the rotary table 2.

A separation gas supply pipe 51 is connected to the center of the top plate 11 of the chamber 1, to supply N₂ gas as the separation gas into a space 52 between the top plate 11 and the core 21. The separation gas supplied into the space 52 is discharged through a narrow space 50 between the protrusion 5 and the rotary table 2 along the surface of the rotary table 2 on which the wafer is placed, toward the periphery of the rotary table 2. The space 50 may be kept at a higher pressure than that in the spaces 481 and 482 by the separation gas. Accordingly, the space 50 suppresses the first reaction gas supplied to the first processing region P1 and the second reaction gas supplied to the second processing region P2 from being mixed with each other through the space 52.

The substrate processing apparatus includes the control unit 100 that controls the operation of the substrate processing apparatus. The substrate processing apparatus is provided with various sensors. As an example of the various sensors, a temperature sensor 60 is provided to measure the temperature of the rotary table 2. The temperature sensor 60 is provided, for example, above the rotary table 2, and may be a radiation thermometer that determines a deviation of the wafer W placed on the placing unit by using the difference in material between the rotary table 2 and the wafer W, or measures the temperature of the rotary table 2. The temperature sensor 60 is disposed in contact or non-contact with the rotary table 2 to measure the temperature of the rotary table 2.

When the temperature sensor 60 is a radiation thermometer, the radiation thermometer is provided, for example, on a window outside the chamber 1, and measures the temperature of an object by measuring the intensity of infrared ray or visible light emitted from the object. By using the radiation thermometer as the temperature sensor 60, the temperature of the rotary table 2 may be measured at a high speed in a non-contact manner. The temperature sensor 60 transmits the measured temperature to the control unit 100. The control unit 100 acquires the temperature measured by the temperature sensor 60, and uses the acquired temperature for controlling the upward/downward movement of the rotary table 2.

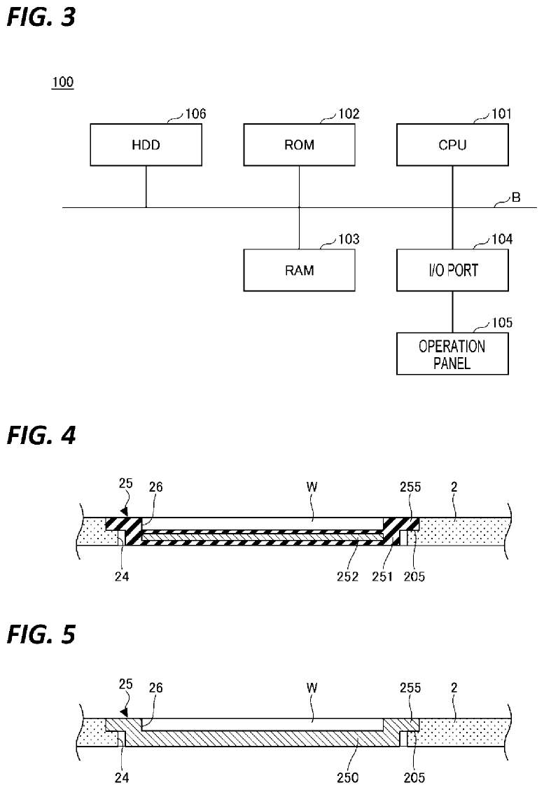

FIG. 3 is a view illustrating an example of a hardware configuration of the control unit 100 according to the embodiment. The control unit 100 includes a central processing unit (CPU) 101, a read only memory (ROM) 102, a random access memory (RAM) 103, an I/O port 104, an operation panel 105, and a hard disk drive (HDD) 106. These components are connected to each other by a bus.

The CPU 101 controls the operation of the control unit 100 based on, for example, programs stored in a storage device such as the HDD 106 or process recipes for performing a film forming process or a cleaning process. The CPU 101 controls the film forming process of the wafer W placed on the rotary table 2 based on a process recipe. The CPU 101 also controls the cleaning process for cleaning the inside of the chamber 1 based on a cleaning recipe.

The ROM 102 is configured with, for example, an electrically erasable programmable ROM (EEPROM), a flash memory, or a hard disk, and is a storage medium that stores, for example, programs or recipes of the CPU 101. The RAM 103 functions as, for example, a work area for the CPU 101.

The I/O port 104 acquires values of various sensors that detect, for example, a temperature, a pressure, and a gas flow rate, from the various sensors attached to the substrate processing apparatus, and transmits the values to the CPU 101. Further, the I/O port 104 outputs control signals output by the CPU 101 to the components (e.g., the rotary table 2 and the vacuum pump 640) of the substrate processing apparatus. The operation panel 105 is connected to the I/O port 104 such that an operator operates the substrate processing apparatus through the operation panel 105.

The HDD 106 is a secondary storage device, and may store, for example, a process recipe or a program, which is information defining procedures for the film forming process or the cleaning process.

Next, the accommodating portion 24 of the rotary table 2 and the holding tray 25 will be further described with reference to FIG. 4. FIG. 4 is an example of a cross-sectional view illustrating the structure of the accommodating portion 24 of the rotary table 2 and the holding tray 25.

The holding tray 25 includes an insulating member 251 where the recess 26 is formed, and a magnetic member 252 disposed in the insulating member 251.

The insulating member 251 is made of an insulating material. The insulating member 251 may be made of an insulating material having a high heat conductivity such as MN or Al₂O₃.

The magnetic member 252 is made of a magnetic material, and is a member induction-heated by the induction heating coil 7. The magnetic member 252 is made of a magnetic material such as Fe or SUS430. The magnetic member 252 is disposed, for example, below the placement surface of the recess 26 on which the wafer W is to be placed.

The holding tray 25 may be formed by covering the magnetic member 252 with the insulating member 251, or may be formed by integrally sintering the insulating member 251 and the magnetic member 252.

The holding tray 25 is supported in the rotary table 2 via a heat conduction suppressing unit that suppresses a heat conduction between the rotary table 2 and the holding tray 25. The heat conduction suppressing unit has a structure that supports the rotary table 2 and the holding tray 25 with a small contact area therebetween.

For example, in the example illustrated in FIG. 4, a flange 255 is formed on the holding tray 25 to extend radially outward from the outer peripheral surface of the circular plate-shaped holding tray 25.

In the accommodating portion 24 of the rotary table 2, an engaging portion 205 is formed in contact with the flange 255 of the holding tray 25. The engaging portion 205 is formed, for example, as a stepped portion protruding radially inward from the inner peripheral surface of the hole-shaped accommodating portion 24.

In this example, the heat conduction suppressing unit is configured with the flange 255 and the engaging portion 205. When the holding tray 25 is disposed in the accommodating portion 24 of the rotary table 2, the holding tray 25 and the accommodating portion 24 of the rotary table 2 are brought into contact with each other at the flange 255 and the engaging portion 205. The heat conduction suppressing unit suppresses the heat conduction between the holding tray 25 and the rotary table 2, by reducing the contact area between the holding tray 25 and the rotary table 2. The configuration of the heat conduction suppressing unit illustrated in FIG. 4 is an example and is not limited thereto.

The heat conduction suppressing unit may be configured by interposing a heat insulating member between the rotary table 2 and the holding tray 25. Accordingly, an insulating material having a high heat conductivity such as Al₂O₃ may be used for the rotary table 2.

The configuration of the holding tray 25 is not limited to the configuration of the holding tray 25 illustrated in FIG. 4. FIG. 5 is another example of the cross-sectional view illustrating the structure of the accommodating portion 24 of the rotary table 2 and the holding tray 25.

The holding tray 25 includes the magnetic member 250 where the recess 26 is formed. The magnetic member 250 is made of a magnetic material, and is a member which is induction-heated by the induction heating coil 7. The magnetic member 250 is made of a magnetic material such as carbon. The surface of the holding tray 25 may be coated with SiC.

The holding tray 25 is supported in the rotary table 2 via the heat conduction suppressing unit (the flange 255 and the engaging portion 205) that suppresses the heat conduction between the rotary table 2 and the holding tray 25. The heat conduction suppressing unit has a structure that supports the rotary table 2 and the holding tray 25 with a small contact area therebetween.

Next, the substrate processing apparatus according to the present embodiment will be described by comparing it with a substrate processing apparatus according to a reference example.

First, the substrate processing apparatus according to the reference example will be described. In the substrate processing apparatus of the reference example, a circular recess for placing the wafer therein is directly formed in the rotary table. A resistance heater is provided below the rotary table. The resistance heater heats the rotary table with radiant heat, thereby heating the wafer placed in the recess of the rotary table.

In the substrate processing apparatus of the reference example, the rotary table having a large heat capacity is heated, and therefore, the power consumption of the resistance heater for heating the wafer to a desired temperature increases. Further, the radiant heat from the resistance heater heats, for example, the bottom 14 of the container body 12, in addition to the rotary table. Thus, the power consumption of the resistance heater for heating the wafer to a desired temperature increases. Further, in the substrate processing apparatus of the reference example, the rotary table having a large heat capacity is heated, and therefore, the temperature controllability is inferior when the temperature of the wafer is increased or decreased.

Meanwhile, according to the substrate processing apparatus of the present embodiment, the holding tray 25 is induction-heated by the induction heating coil 7. That is, the heat capacity of the object to be heated is smaller than that in the reference example. Thus, the power consumption of the induction heating coil 7 for heating the wafer W to a desired temperature may be reduced as compared with the reference example. Further, by using the induction heating, the heating of, for example, the bottom 14 of the container body 12 may be suppressed, so that the the power consumption of the induction heating coil 7 for heating the wafer W to a desired temperature may be reduced compared with the reference example. According to the substrate processing apparatus of the present embodiment, since the heat capacity of the object to be heated is smaller than that in the reference example, the temperature controllability may be improved when the temperature of the wafer W is increased or decreased.

In the substrate processing apparatus of the reference example, the rotary table is heated, and therefore, the same film as that on the wafer is formed on the rotary table as well. Accordingly, the consumption of a process gas increases. The amount of a reaction by-product gas produced by the film forming process also increases. Further, since the range of an object to be cleaned is widened, the consumption of a cleaning gas also increases. The range of a particle generation source that generates particles due to a separation of film also becomes wide.

Meanwhile, the substrate processing apparatus of the present embodiment induction-heats the holding tray 25, and has the structure (the flange 255 and the engaging portion 205) that suppresses the heat transfer between the holding tray 25 and the rotary table 2. Accordingly, the formation of a film on the rotary table 2 may be suppressed. Further, the consumption of the process gas may be reduced. The amount of the reaction by-product gas may also be reduced. The consumption of the cleaning gas may also be reduced. Further, since the range of the particle generation source that generates particles due to a separation of film may be narrowed, the adhesion of, for example, particles to the substrate W may be suppressed.

In the substrate processing apparatus of the reference example, the rotary table emits heat from its central shaft. Thus, a temperature gradient may occur in the radial direction of the rotary table.

Meanwhile, in the substrate processing apparatus of the present embodiment, the holding tray 25 is supported in the rotary table 2 via the heat conduction suppressing unit, so that the temperature gradient in the radial direction of the rotary table 2 may be suppressed.

Further, the magnetic members 250 and 252 of the holding tray 25 are induction-heated by supplying a radio-frequency current to the induction heating coil 7 from a radio-frequency power supply (not illustrated). However, the present invention is limited thereto. The induction heating may be performed by forming a constant magnetic field by the induction heating coil 7 and rotating the rotary table 2, thereby applying the change of the magnetic field to the magnetic members 250 and 252 of the holding tray 25. Alternatively, a ground line (not illustrated) may be connected to the magnetic members 250 and 252 of the holding tray 25, and an opening/closing switch (not illustrated) may be provided on the ground line. As a result, by closing the opening/closing switch, the induction heating of the magnetic members 250 and 252 of the holding tray 25 may be suppressed. By opening the opening/closing switch, the magnetic members 250 and 252 of the holding tray 25 may be induction-heated.

According to an aspect, it is possible to provide a substrate heating apparatus and a substrate processing apparatus, which may reduce a power consumption required for a heating and improve a temperature controllability.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate heating apparatus comprising:
an induction heating coil;
a holding tray including a substrate holder that places and holds a substrate thereon, and configured to be induction-heated by the induction heating coil; and
a rotary table configured to support the holding tray and provided to be freely rotatable.

2. The substrate heating apparatus according to claim 1, wherein the holding tray includes an insulating body where the substrate holder is formed, and a magnetic body disposed in the insulating body.

3. The substrate heating apparatus according to claim 2, wherein the magnetic body is disposed below a placement surface of the substrate holder on which the substrate is placed.

4. The substrate heating apparatus according to claim 2, wherein
the insulating body is formed of AlN or Al₂O₃, and
the magnetic body is formed of Fe or SUS430.

5. The substrate heating apparatus according to claim 1, wherein the holding tray includes a magnetic body where the substrate holder is formed.

6. The substrate heating apparatus according to claim 4, wherein the magnetic body is formed of carbon.

7. The substrate heating apparatus according to claim 1, wherein the rotary table is formed of quartz.

8. The substrate heating apparatus according to claim 1, wherein the rotary table supports the holding tray via a heat conduction suppressor that suppresses a heat conduction between the rotary table and the holding tray.

9. The substrate heating apparatus according to claim 8, wherein
the heat conduction suppressor includes:
a flange provided on an outer periphery of the holding tray, and
an engaging portion provided on the rotary table, and
the holding tray and the rotary table are in contact with each other at the flange and the engaging portion.

10. A substrate processing apparatus comprising the substrate heating apparatus according to claim 9.
